(19) United States
(12) Patent Application Publication
(10) Pub. No.: US 2021/0267054 A1
(43) Pub. Date: Aug. 26, 2021

(54) CIRCUIT FORMATION METHOD AND CIRCUIT FORMATION DEVICE

(71) Applicant: FUJI CORPORATION, Chiryu (JP)

(72) Inventors: Tasuku TAKEUCHI, Kariya-shi (JP); Ryojiro TOMINAGA, Okazaki-shi (JP); Ryo SAKAKIBARA, Chiryu-shi (JP)

(73) Assignee: FUJI CORPORATION, Chiryu (JP)

(21) Appl. No.: 17/253,398

(22) PCT Filed: Jul. 13, 2018
(86) PCT No.: PCT/JP2018/026444

§ 371 Date: Dec. 17, 2020

(51) Int. Cl. H05K 1/09; H05K 3/32; B22F 1/00; H05K 3/12

(52) U.S. Cl. CPC H05K 1/092; H05K 3/32; H05K 2201/0242; H05K 3/125; H05K 2203/013; B22F 1/0018

(57) ABSTRACT

A circuit formation method includes a wiring formation step of forming a wiring by applying a metal-containing liquid containing nanometer-sized metal fine particles onto a base and firing the metal-containing liquid, a paste application step of applying a resin paste containing micrometer-sized metal particles to be connected to the wiring formed in the wiring formation step, and a component placement step of placing a component having an electrode on the base, such that the electrode is in contact with the resin paste applied in the paste application step.

### TECHNICAL FIELD

The present application relates to a circuit formation method of a circuit including a wiring that is formed by using a metal-containing liquid containing nanometer-sized metal fine particles, and a circuit formation device thereof.

### BACKGROUND ART As described in the following Patent Literature, a technique for forming a wiring, using a metal-containing liquid containing nanometer-sized metal fine particles, has been developed.

### PATENT LITERATURE

Patent Literature 1: JP-A-11-163499

### BRIEF SUMMARY

### Technical Problem

Appropriate formation of a circuit including a wiring, being formed using a metal-containing liquid, is ensured.

### Solution to Problem

In order to solve the above problems, the present specification discloses a circuit formation method including a wiring formation step of forming a wiring by applying a metal-containing liquid containing nanometer-sized metal fine particles onto a base and firing the metal-containing liquid, a paste application step of applying a resin paste containing micrometer-sized metal particles to be connected to the wiring formed in the wiring formation step, and a component placement step of placing a component having an electrode on the base, such that the electrode is in contact with the resin paste applied in the paste application step.

In order to solve the above problems, the present specification discloses a circuit formation device including a first application device configured to apply a metal-containing liquid containing nanometer-sized metal fine particles, a second application device configured to apply a resin paste containing micrometer-sized metal particles, a firing device configured to fire the metal-containing liquid, a holding device configured to hold a component having an electrode, and a control device, in which the control device includes a wiring formation section configured to form a wiring by applying the metal-containing liquid onto a base by the first application device and firing the metal-containing liquid by the firing device, a paste application section configured to apply the resin paste by the second application device to be connected to the wiring formed by the wiring formation section, and a component placement section configured to place the component on the base by the holding device, such that the electrode is in contact with the resin paste applied by the paste application section.

### Advantageous Effects

According to the present disclosure, the appropriate formation of the circuit including the wiring formed using the metal-containing liquid is ensured by connecting the electrode of the component and the wiring via the resin paste.

### BRIEF DESCRIPTION OF DRAWINGS

FIG. 1 is a diagram showing a circuit formation device.

FIG. 2 is a block diagram showing a control device.

FIG. 3 is a cross-sectional view showing a circuit in a state where a resin laminate is formed.

FIG. 4 is a cross-sectional view showing the circuit in a state where a wiring is formed on the resin laminate.

FIG. 5 is a cross-sectional view showing the circuit in a state where an electronic component is mounted.

FIG. 6 is a cross-sectional view showing the circuit in a state where the electronic component is peeled off.

FIG. 7 is a cross-sectional view showing the circuit in a state where the wiring is formed by a method of a first embodiment.

FIG. 8 is a cross-sectional view showing the circuit in a state where conductive resin paste is formed by the method of the first embodiment.

FIG. 9 is a cross-sectional view showing the circuit in a state where the electronic component is mounted by the method of the first embodiment.

FIG. 10 is a cross-sectional view showing the circuit in a state where the conductive resin paste is formed by a method of a second embodiment.

FIG. 11 is a cross-sectional view showing the circuit in a state where the electronic component is mounted by the method of the second embodiment.

FIG. 12 is a cross-sectional view taken along a line AA in FIG. 11.

### DESCRIPTION OF EMBODIMENTS

### First Embodiment

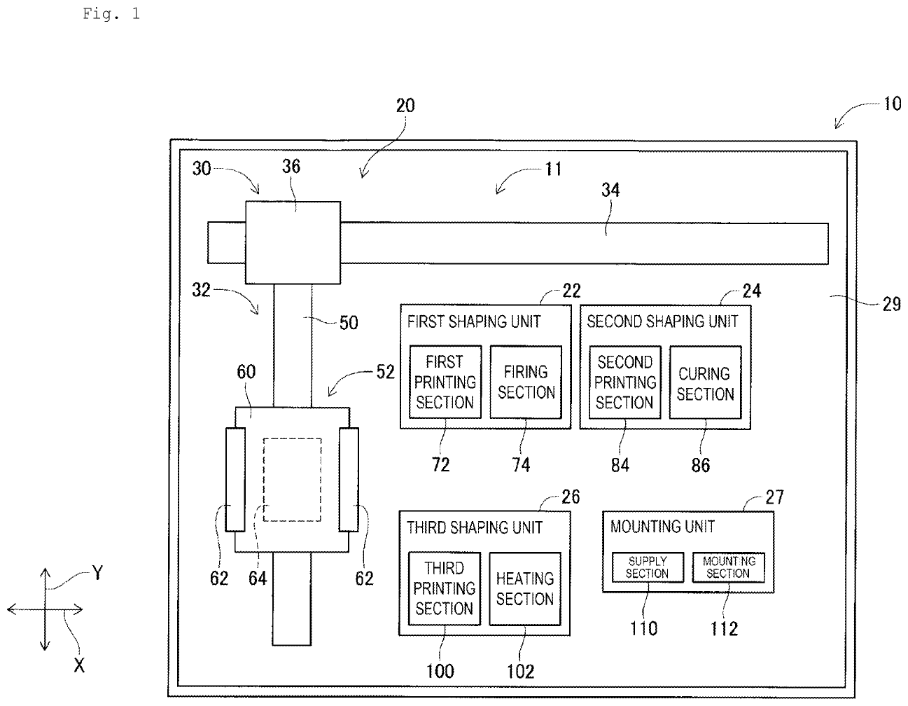

FIG. 1 shows circuit formation device 10. Circuit formation device 10 includes conveyance device 20, first shaping unit 22, second shaping unit 24, third shaping unit 26, mounting unit 27, and control device (see FIG. 2) 28. Conveyance device 20, first shaping unit 22, second shaping unit 24, third shaping unit 26, and mounting unit 27 are disposed on base 29 of circuit formation device 10. Base 29 has a generally rectangular shape, and in the following description, a longitudinal direction of base 29 is referred to as an X-axis direction, a short direction of base 29 is referred to as a Y-axis direction, and a direction orthogonal to both the X-axis direction and the Y-axis direction is referred to as a Z-axis direction.

Conveyance device 20 includes X-axis slide mechanism 30 and Y-axis slide mechanism 32. X-axis slide mechanism 30 has X-axis slide rail 34 and X-axis slider 36. X-axis slide rail 34 is disposed on base 29 to extend in the X-axis direction. X-axis slider 36 is held by X-axis slide rail 34 to be slidable in the X-axis direction. Further, X-axis slide mechanism 30 has electromagnetic motor (see FIG. 2) 38, and moves X-axis slider 36 to any position in the X-axis direction by driving electromagnetic motor 38. Furthermore, Y-axis slide mechanism 32 has Y-axis slide rail 50 and stage 52. Y-axis slide rail 50 is disposed on base 29 to extend in the Y-axis direction and is movable in the X-axis direction. A first end portion of Y-axis slide rail 50 is connected to X-axis slider 36. Stage 52 is held on Y-axis slide rail 50 to be slidable in the Y-axis direction. Further, Y-axis slide mechanism 32 has electromagnetic motor (see FIG. 2) 56, and moves stage 52 to any position in the Y-axis direction by driving electromagnetic motor 56. In this manner, stage 52 is moved to any position on base 29 with driving of X-axis slide mechanism 30 and Y-axis slide mechanism 32.

Stage 52 has base plate 60, holding devices 62, and lifting and lowering device 64. Base plate 60 is formed in a flat plate shape, and a board is placed on an upper surface of base plate 60. Holding devices 62 are provided on both sides of base plate 60 in the X-axis direction. The board placed on base plate 60 is fixedly held by sandwiching both edge portions of the board in the X-axis direction with holding devices 62. In addition, lifting and lowering device 64 is disposed under base plate 60, and lifts and lowers base plate 60.

First shaping unit 22 is a unit that shapes a wiring on the board placed on base plate 60 of stage 52, and has first printing section 72 and firing section 74. First printing section 72 has inkjet head (see FIG. 2) 76, and inkjet head 76 linearly discharges metal ink. The metal ink is ink obtained by dispersing nanometer-sized metal fine particles in a solvent. A surface of the metal fine particle is coated with a dispersant and aggregation in the solvent is prevented. Inkjet head 76 discharges the metal ink from multiple nozzles by, for example, a piezo method using a piezoelectric element.

Firing section 74 has laser irradiation device (see FIG. 2) 78. Laser irradiation device 78 is a device that irradiates the discharged metal ink with laser, and the metal ink irradiated with the laser is fired to form the wiring. Firing of the metal ink is a phenomenon in which energy is applied so as to vaporize the solvent and decompose a protective film of the metal fine particle, that is, the dispersant, and the metal fine particles are contacted or fused with each other, and thus conductivity is increased. Then, the metal ink is fired to form a metal wiring.

Further, second shaping unit 24 is a unit that shapes a resin layer on the board placed on base plate 60 of stage 52, and has second printing section 84 and curing section 86. Second printing section 84 has inkjet head (see FIG. 2) 88, and inkjet head 88 discharges an ultraviolet curable resin. The ultraviolet curable resin is a resin that is cured by irradiation with ultraviolet rays. Inkjet head 88 may be, for example, a piezo type inkjet head using a piezoelectric element, or may be a thermal type inkjet head in which a resin is heated to generate air bubbles, which are discharged from multiple nozzles.

Curing section 86 has flattening device (see FIG. 2) 90 and irradiation device (see FIG. 2) 92. Flattening device 90 flattens an upper surface of the ultraviolet curable resin discharged by inkjet head 88, and for example, scrapes up excess resin by a roller or a blade while smoothening the surface of the ultraviolet curable resin, to make the thickness of the ultraviolet curable resin uniform. Further, irradiation device 92 includes a mercury lamp or an LED as a light source, and irradiates the discharged ultraviolet curable resin with ultraviolet rays. With this, the discharged ultraviolet curable resin is cured to form the resin layer.

Third shaping unit 26 is a unit that shapes a connection part between an electrode of an electronic component and the wiring on the board placed on base plate 60 of stage 52, and has third printing section 100 and heating section 102. Third printing section 100 has dispense head (see FIG. 2) 106, and dispense head 106 discharges conductive resin paste. The conductive resin paste is paste in which the micrometer-sized metal particles are dispersed in a resin cured by heating. Incidentally, the metal particles are flake-shaped particles. Since a viscosity of the conductive resin paste is relatively high compared to that of the metal ink, dispense head 106 discharges the conductive resin paste from one nozzle having a diameter larger than a diameter of the nozzle of inkjet head 76.

Heating section 102 has heater (see FIG. 2) 108. Heater 108 is a device that heats the discharged conductive resin paste, and a resin is cured in the heated conductive resin paste. At this time, in the conductive resin paste, the cured resin is contracted, and the flake-shaped metal particles dispersed in the resin come into contact with each other. As a result, the conductive resin paste exhibits conductivity.

In addition, mounting unit 27 is a unit that mounts the electronic component on the board placed on base plate 60 of stage 52, and has supply section 110 and mounting section 112. Supply section 110 has multiple tape feeders (see FIG. 2) 114 that feed the taped electronic components one by one, and supplies the electronic component to a supply position. Supply section 110 is not limited to tape feeder 114, and may be a tray-type supply device that supplies the electronic component by picking up the electronic component from a tray. Supply section 110 may be configured to include both the tape-type and the tray-type, or other type of supply device.

Mounting section 112 has mounting head (see FIG. 2) 116 and moving device (see FIG. 2) 118. Mounting head 116 has a suction nozzle (not shown) for picking up and holding the electronic component. The suction nozzle picks up and holds the electronic component by picking up air as a negative pressure is supplied from a positive and negative pressure supply device (not shown). As a slight positive pressure is supplied from the positive and negative pressure supply device, the electronic component is separated. In addition, moving device 118 moves mounting head 116 between the supply position of the electronic component by tape feeder 114 and the board placed on base plate 60. As a result, in mounting section 112, the electronic component supplied from tape feeder 114 is held by the suction nozzle, and the electronic component held by the suction nozzle is mounted on the board.

Further, as shown in FIG. 2, control device 28 includes controller 120 and multiple drive circuits 122. Multiple drive circuits 122 are connected to electromagnetic motors 38, 56, holding device 62, lifting and lowering device 64, inkjet head 76, laser irradiation device 78, inkjet head 88, flattening device 90, irradiation device 92, dispense head 106, heater 108, tape feeder 114, mounting head 116, and moving device 118. Controller 120 includes CPU, ROM, RAM, or the like, mainly includes a computer, and is connected to multiple drive circuits 122. Accordingly, Controller 120 controls the operations of conveyance device 20, first shaping unit 22, second shaping unit 24, third shaping unit 26, and mounting unit 27.

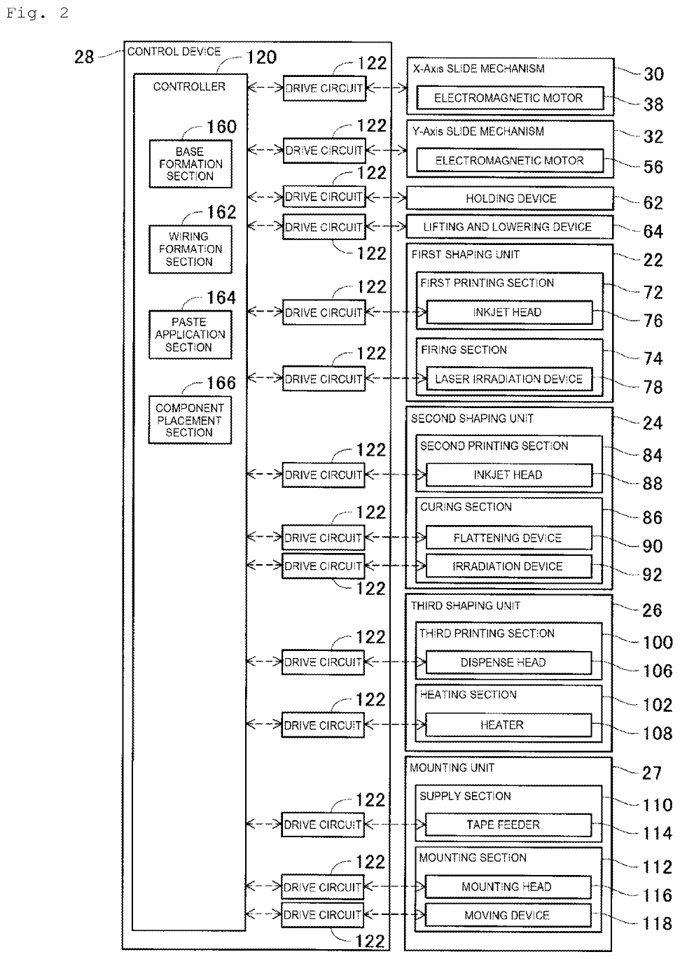

With the configuration described above, in circuit formation device 10, a resin laminate is formed on board (see FIG. 3) 70, and the wiring is formed on an upper surface of the resin laminate. In the conventional method, although the electrode of the electronic component is directly connected to the wiring, the adhesion between the resin laminate and the wiring is weak, therefore, when external stress is applied to the electronic component, the wiring may be peeled off from the resin laminate and be broken.

Specifically, board 70 is set on base plate 60 of stage 52, and stage 52 is moved under second shaping unit 24. Then, in second shaping unit 24, resin laminate 130 is formed on board 70, as shown in FIG. 3. Resin laminate 130 is formed by repeating discharge of the ultraviolet curable resin from inkjet head 88 and irradiation of the discharged ultraviolet curable resin with ultraviolet rays by irradiation device 92.

More specifically, in second printing section 84 of second shaping unit 24, inkjet head 88 discharges the ultraviolet curable resin in a thin film shape onto an upper surface of board 70. Subsequently, when the ultraviolet curable resin is discharged in a thin film shape, the ultraviolet curable resin is flattened by flattening device 90 in curing section 86, such that the ultraviolet curable resin has a uniform film thickness. Then, irradiation device 92 irradiates the thin film-shaped ultraviolet curable resin with ultraviolet rays. As a result, thin film-shaped resin layer 132 is formed on board 70.

Subsequently, inkjet head 88 discharges the ultraviolet curable resin in a thin film shape onto thin film-shaped resin layer 132. Then, the thin film-shaped ultraviolet curable resin is flattened by flattening device 90, irradiation device 92 irradiates the ultraviolet curable resin discharged in a thin film shape with ultraviolet rays, and as a result, thin film-shaped resin layer 132 is laminated on thin film-shaped resin layer 132. As described above, by repeating the discharge of the ultraviolet curable resin onto thin film-shaped resin layer 132 and the irradiation of ultraviolet rays, multiple resin layers 132 are laminated and resin laminate 130 is formed.

When resin laminate 130 is formed by the above-described procedure, stage 52 is moved under first shaping unit 22. Then, in first printing section 72 of first shaping unit 22, inkjet head 76 linearly discharges the metal ink onto the upper surface of resin laminate 130 in accordance with a circuit pattern. Subsequently, in firing section 74 of first shaping unit 22, laser irradiation device 78 irradiates the metal ink discharged in accordance with the circuit pattern with laser. As a result, the metal ink is fired, and wiring 136 is formed on resin laminate 130 as shown in FIG. 4.

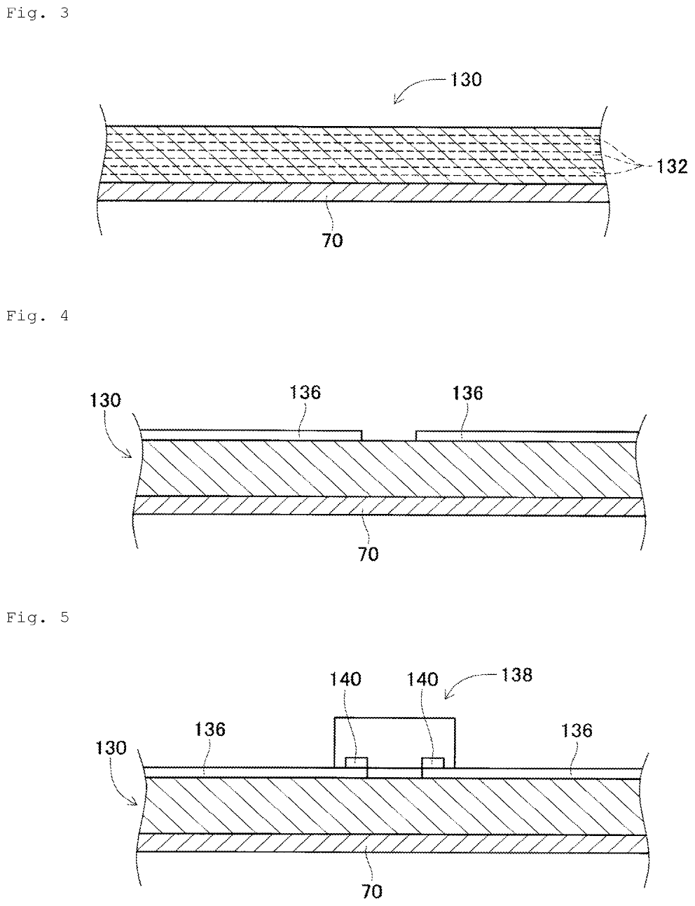

Subsequently, when wiring 136 is formed on resin laminate 130, stage 52 is moved under mounting unit 27. In mounting unit 27, electronic component 138 is supplied by tape feeder 114 and electronic component 138 is held by the suction nozzle of mounting head 116. Then, mounting head 116 is moved by moving device 118, and electronic component 138 held by the suction nozzle is mounted on the upper surface of resin laminate 130 as shown in FIG. 5. At this time, electronic component 138 is mounted on the upper surface of resin laminate 130, such that electrode 140 of electronic component 138 is in contact with wiring 136. In this manner, electronic component 138 is mounted on resin laminate 130 in an electrifiable state to form the circuit.

Note that, since both wiring 136 and electrode 140 of electronic component 138 are made of metal, the adhesion therebetween is high, but since resin laminate 130 is made of resin, the adhesion to wiring 136 is low. Therefore, when external stress is applied to electronic component 138, as shown in FIG. 6, electronic component 138 may be peeled off from resin laminate 130 together with wiring 136, which is connected to the electrode and wiring 136 may be broken.

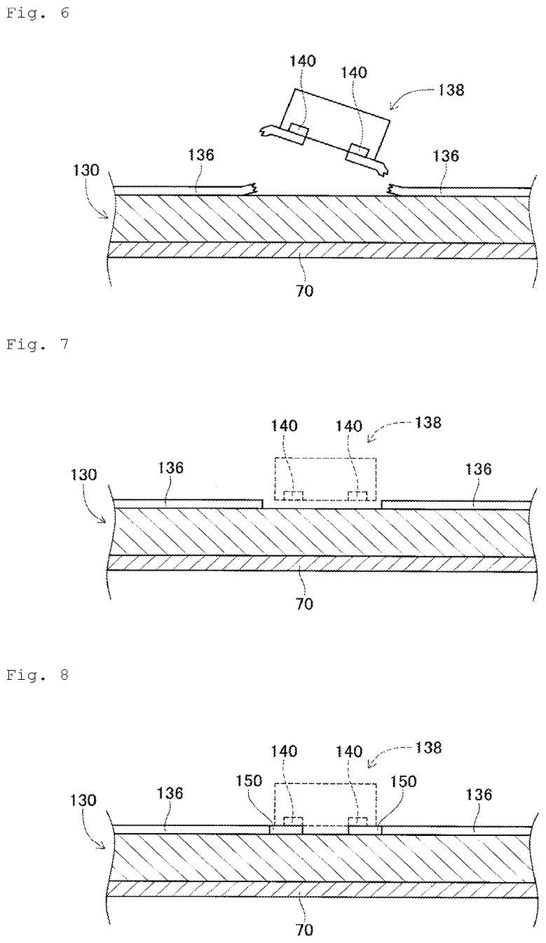

In view of the above description, in circuit formation device 10, electrode 140 of electronic component 138 is not directly connected to wiring 136 and is indirectly connected to wiring 136 via the conductive resin paste. Specifically, when wiring 136 is formed on resin laminate 130, the metal ink is discharged onto the upper surface of resin laminate 130, such that an end portion of wiring 136 is not to overlap with a disposition planned position of electrode 140 of electronic component 138. That is, the metal ink is discharged onto the upper surface of resin laminate 130, such that an end of the metal ink is positioned outside an outer edge of the disposition planned position of electrode 140 of electronic component 138. In this manner, as shown in FIG. 7, wiring 136 is formed on the upper surface of resin laminate 130 not to overlap with the disposition planned position of electrode 140 of electronic component 138. In FIG. 7, wiring 136 is formed on the upper surface of resin laminate 130 not to overlap with not only the disposition planned position of electrode 140, but also a disposition planned position of electronic component 138. Further, electronic component 138 in FIG. 7 is marked with a dotted line to indicate the disposition planned position of electrode 140, and electronic component 138 does not exist at a time of work in FIG. 7.

As described above, when wiring 136 is formed not to overlap with the disposition planned position of electrode 140, stage 52 is moved under third shaping unit 26. Then, in third printing section 100 of third shaping unit 26, dispense head 106 discharges the conductive resin paste onto the upper surface of resin laminate 130. At this time, conductive resin paste 150, as shown in FIG. 8, is discharged onto the upper surface of resin laminate 130 to be connected to the end portion of wiring 136 and to extend to the disposition planned position of electrode 140. That is, conductive resin paste 150 is discharged, such that a first end portion is connected to the end portion of wiring 136, and a second end portion is positioned inside the outer edge of the disposition planned position of electrode 140. Also, electronic component 138 in FIG. 8 is marked with a dotted line to indicate the disposition planned position of electrode 140, and electronic component 138 does not exist at a time of work in FIG. 8.

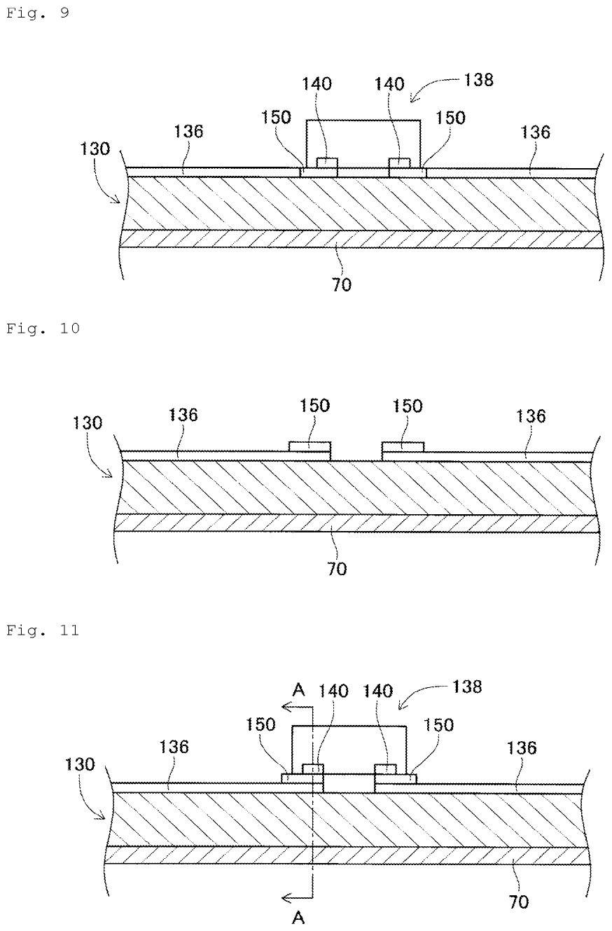

Thus, when the conductive resin paste is discharged onto the upper surface of resin laminate 130, stage 52 is moved under mounting unit 27. In mounting unit 27, electronic component 138 supplied by tape feeder 114 is held by the suction nozzle of mounting head 116, and electronic component 138 is mounted on the upper surface of resin laminate 130. At this time, as shown in FIG. 9, electronic component 138 is mounted on the upper surface of resin laminate 130, such that electrode 140 of electronic component 138 is in contact with conductive resin paste 150.

Subsequently, when electronic component 138 is mounted, stage 52 is moved under third shaping unit 26. In third shaping unit 26, heater 108 heats conductive resin paste 150 in heating section 102. As a result, conductive resin paste 150 exhibits the conductivity, electrode 140 of electronic component 138 is electrically connected to wiring 136 via conductive resin paste 150.

Thus, when electrode 140 of electronic component 138 is electrically connected to wiring 136 via conductive resin paste 150, electrode 140 adheres to conductive resin paste 150, and conductive resin paste 150 adheres to resin laminate 130. As described above, conductive resin paste 150 in which the flake-shaped metal particles dispersed in the resin are in contact with each other in the cured resin is made of a resin material and a metal material. Therefore, the adhesion between electrode 140 and conductive resin paste 150 is high, and the adhesion between conductive resin paste 150 and resin laminate 130 is also high. As a result, even when external stress is applied to electronic component 138, it is possible to prevent electronic component 138 from being peeled off from resin laminate 130, and prevent wiring 136 from being broken.

Further, since conductive resin paste 150 is made of the resin material and the metal material, the conductivity thereof is low compared to wiring 136, but a disposition location of conductive resin paste 150 is a small area under electrode 140. Therefore, the decrease in conductivity due to conductive resin paste 150 is very small.

In addition, as described above, the metal ink is discharged by inkjet head 76 because the viscosity of the metal ink is low and the conductive resin paste is discharged by dispense head 106 because the viscosity of the conductive resin paste is high. Therefore, it is possible to discharge the metal ink, which is the base of wiring 136 constituting most of the circuit, with high accuracy, to form a dense circuit.

Furthermore, by connecting electrode 140 and wiring 136 via conductive resin paste 150 made of the resin material and the metal material, types of the ultraviolet curable resin and the metal ink can be easily selected. That is, in a case where electrode 140 and wiring 136 are directly connected to each other as in the conventional art, the types of the ultraviolet curable resin and the metal ink are selected in consideration of each of raw materials in order to increase the adhesion between wiring 136 and resin laminate 130 as much as possible. On the other hand, in a case where conductive resin paste 150 is used, it is not necessary to consider the adhesion between wiring 136 and resin laminate 130, and therefore, the types of the ultraviolet curable resin and the metal ink can be easily selected.

Controller 120 of control device 28 includes base formation section 160, wiring formation section 162, paste application section 164, and component placement section 166 as shown in FIG. 2. Base formation section 160 is a functional section for forming resin laminate 130. Wiring formation section 162 is a functional section for forming wiring 136. Paste application section 164 is a functional section for discharging conductive resin paste 150. Component placement section 166 is a functional section for placing electronic component 138.

### Second Embodiment

In the first embodiment, conductive resin paste 150 is formed to be connected to the end portion of wiring 136, whereas in the second embodiment, conductive resin paste 150 is formed on wiring 136. More specifically, when wiring 136 is formed on resin laminate 130, the metal ink is discharged onto the upper surface of resin laminate 130 in the same manner as in the conventional method. That is, the metal ink is discharged onto the upper surface of resin laminate 130, such that the end of the metal ink is positioned inside the outer edge of the disposition planned position of electrode 140 of electronic component 138. As a result, as shown in FIG. 4, wiring 136 having the same shape as the conventional method is formed on the upper surface of resin laminate 130.

Subsequently, when wiring 136 is formed, stage 52 is moved under third shaping unit 26. Then, in third printing section 100 of third shaping unit 26, dispense head 106 discharges conductive resin paste 150 onto wiring 136. At this time, conductive resin paste 150, as shown in FIG. 10, is discharged onto the disposition planned position of electrode 140 in an upper surface of wiring 136. Conductive resin paste 150 is discharged to cover the end portion of wiring 136. As a result, as shown in FIG. 12, conductive resin paste 150 covers the entire end portion of wiring 136, and an edge portion thereof adheres to the upper surface of resin laminate 130.

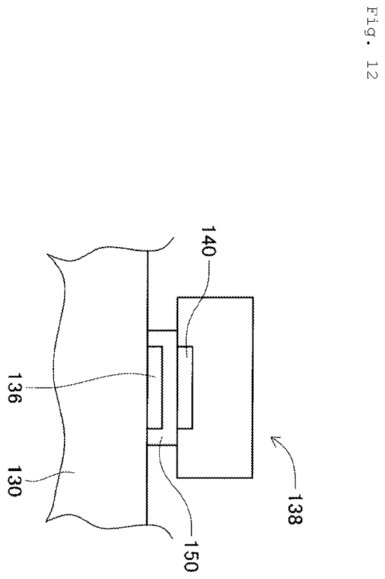

Then, when conductive resin paste 150 is discharged to cover the end portion of wiring 136 at the disposition planned position of electrode 140, stage 52 is moved under mounting unit 27. In mounting unit 27, electronic component 138 is held by the suction nozzle of mounting head 116, and electronic component 138 is mounted on the upper surface of resin laminate 130. At this time, as shown in FIG. 11, electronic component 138 is mounted on the upper surface of resin laminate 130, such that electrode 140 of electronic component 138 is in contact with conductive resin paste 150.

Subsequently, when electronic component 138 is mounted, stage 52 is moved under third shaping unit 26, and heater 108 heats conductive resin paste 150 in heating section 102. As a result, conductive resin paste 150 exhibits the conductivity, electrode 140 of electronic component 138 is electrically connected to wiring 136 via conductive resin paste 150.

Like this, when conductive resin paste 150 is discharged to cover the end portion of wiring 136 at the disposition planned position of electrode 140, electrode 140 of electronic component 138 is electrically connected to wiring 136 via conductive resin paste 150. As a result, a circuit of the second embodiment exhibits the same effect as the circuit of the first embodiment. In the circuit of the second embodiment, as shown in FIG. 12, conductive resin paste 150 between electrode 140 and wiring 136 is electrified by the film thickness of conductive resin paste 150. Therefore, the decrease in conductivity due to conductive resin paste 150 can be minimized.

On the other hand, in a method of the second embodiment, conductive resin paste 150 covers the end portion of wiring 136, and an occupied area of conductive resin paste 150 is increased. Therefore, when a distance between the electrodes in electronic component 138 is small, conductive resin paste 150 connected to one electrode and conductive resin paste 150 connected to the other electrode is brought into contact with each other, and a short circuit may occur. In consideration of the above, when a circuit including an electronic component in which the distance between the electrodes is small is formed, it is preferable to adopt the circuit formation method of the first embodiment.

In the above embodiment, circuit formation device 10 is an example of a circuit formation device. Control device 28 is an example of a control device. Inkjet head 76 is an example of a first application device. Laser irradiation device 78 is an example of a firing device. Dispense head 106 is an example of a second application device. Mounting head 116 is an example of a holding device. The metal ink is an example of a metal-containing liquid. Resin laminate 130 is an example of a base. Resin layer 132 is an example of a resin layer. Wiring 136 is an example of a wiring. Electronic component 138 is an example of a component. Electrode 140 is an example of an electrode. Conductive resin paste 150 is an example of a resin paste. Wiring formation section 162 is an example of a wiring formation section. Paste application section 164 is an example of a paste application section. Component placement section 166 is an example of a component placement section. A step performed by base formation section 160 is an example of a base formation step. A step performed by wiring formation section 162 is an example of a wiring formation step. A step performed by paste application section 164 is an example of a paste application step. A step performed by component placement section 166 is an example of a component placement step.

The present disclosure is not limited to the embodiments described above, and can be implemented in various embodiments with various modifications and improvements based on the knowledge of those skilled in the art. For example, in the above embodiment, a resin cured by heating is adopted as conductive resin paste 150, but a resin cured by irradiation with ultraviolet rays or the like may be adopted.

In the above embodiment, conductive resin paste 150 is discharged to resin laminate 130 by dispense head 106, but conductive resin paste 150 may be transferred to resin laminate 130 by a stamp. In addition, conductive resin paste 150 may be printed on resin laminate 130 by screen printing.

### REFERENCE SIGNS LIST

10 Circuit formation device, 28 control device, 76 inkjet head (first application device), 78 laser irradiation device (firing device), 106 dispense head (second application device), 116 mounting head (holding device), 130 resin laminate (base), 132 resin layer, 136 wiring, 138 electronic component (component), 140 electrode, 150 conductive resin paste (resin paste), 160 base formation section (base formation step), 162 wiring formation section (wiring formation step), 164 paste application section (paste application step), 166 component placement section (component placement step)

1. A circuit formation method comprising:
a wiring formation step of forming a wiring by applying a metal-containing liquid containing nanometer-sized metal fine particles onto a base and firing the metal-containing liquid;
a paste application step of applying a resin paste containing micrometer-sized metal particles to be connected to the wiring formed in the wiring formation step; and
a component placement step of placing a component having an electrode on the base, such that the electrode is in contact with the resin paste applied in the paste application step.

2. The circuit formation method according to claim 1,
wherein the paste application step is a step of applying the resin paste on the wiring formed in the wiring formation step.

3. The circuit formation method according to claim 1,
wherein the paste application step is a step of applying the resin paste to be connected to an end portion of the wiring formed in the wiring formation step.

4. The circuit formation method according to claim 1, further comprising:
a base formation step of forming the base by curing a curable resin applied in a thin film shape to form a resin layer and laminating the resin layer.

5. A circuit formation device comprising:
a first application device configured to apply a metal-containing liquid containing nanometer-sized metal fine particles;
a second application device configured to apply a resin paste containing micrometer-sized metal particles;
a firing device configured to fire the metal-containing liquid;
a holding device configured to hold a component having an electrode; and
a control device,
wherein the control device includes
a wiring formation section configured to form a wiring by applying the metal-containing liquid onto a base by the first application device and firing the metal-containing liquid by the firing device,
a paste application section configured to apply the resin paste by the second application device to be connected to the wiring formed by the wiring formation section, and
a component placement section configured to place the component on the base by the holding device, such that the electrode is in contact with the resin paste applied by the paste application section.
